(19) United States
(12) Patent Application Publication
(10) Pub. No.: US 2020/0294949 A1
(43) Pub. Date: Sep. 17, 2020

(54) HOTSPOT THERMAL MANAGEMENT OF POWER ELECTRONIC PACKAGE WITH NANO DIE ATTACH MATERIAL

(71) Applicant: LITTELFUSE, INC., Chicago, IL (US)

(72) Inventor: Be-nazir Khan, Beverly, MA (US)

(73) Assignee: LITTELFUSE, INC., Chicago, IL (US)

(21) Appl. No.: 16/351,744

(22) Filed: Mar. 13, 2019

(51) Int. Cl. H01L 23/00; H01L 23/31; H01L 23/373; H01L 25/07; H01L 25/00

(52) U.S. Cl. CPC H01L 24/29; H01L 23/3121; H01L 23/3735; H01L 24/32; H01L 24/83; H01L 25/072; H01L 2924/35121; H01L 2224/29239; H01L 2224/32225; H01L 2224/8384; H01L 2924/10272; H01L 2924/13055; H01L 2924/13091; H01L 25/50

(57) ABSTRACT

Embodiments herein are directed to semiconductor package assemblies and methods of forming. In some embodiments, a semiconductor package assembly includes a substrate, a first metallization layer disposed adjacent the substrate, and a semiconductor die disposed in thermal contact with the first metallization layer. The semiconductor package assembly may further include a die attach layer disposed between the semiconductor die and the first metallization layer, the die attach layer including a polymer matrix and a nano-metal particle filler.

### BACKGROUND OF THE DISCLOSURE

### Field of the Disclosure

The present disclosure relates to power electronic packaging and, in particular, to hotspot thermal management of power electronic packages with nano die attach material.

### Discussion of Related Art

Packaging constitutes the last phase of single or multiple chip device fabrication and provides the necessary interconnects between chip and chip carrier. Packaging further provides an enclosure protecting against environmental influences such as chemical corrosion and damage due to thermal and mechanical impact or irradiation.

Thermo-mechanical stress induced defects have become a reliability issue impacting the lifetime of electronic devices. For example, delamination at the contact interface between chip and chip carrier, and crack formation at or in the vicinity of the interface, are known issues. A cause for the appearance of such defects is the application of high temperature or high-pressure processes during device manufacturing including assembly and packaging.

As a result, thermal management of the package is critical for power applications. Optimum thermal design in high-power package lowers die temperature to improve the performance and reliability, which is critical for power applications. In electronic packaging, a solder die attach material is often used to attach the semiconductor chips on the substrate. However, solder is prone to thermal degradation, creep, and fatigue with temperature and time. Other solder die attach materials also experience limitations, especially as the die size of power semiconductor devices increases. Accordingly, what is needed is an improved power electronic package that overcomes at least the above deficiencies of the current art.

### SUMMARY OF THE DISCLOSURE

In one or more embodiments, a semiconductor package assembly includes a substrate, a first metallization layer disposed adjacent the substrate, and a semiconductor die disposed in thermal contact with the first metallization layer. The semiconductor package assembly may further include a die attach layer disposed between the semiconductor die and the first metallization layer, the die attach layer including a polymer matrix and a nano-metal particle filler.

In one or more embodiments, a semiconductor package assembly may include a substrate, a copper layer disposed adjacent to the substrate, and a semiconductor die disposed in thermal contact with the copper layer. The semiconductor package assembly may further include a die attach layer disposed between the semiconductor die and the copper layer, the die attach layer comprising a polymer matrix and a nano-metal particle filler.

In one or more embodiments, a method of forming a semiconductor package assembly may include attaching a copper layer to a substrate, providing a semiconductor die in thermal contact with the copper layer, and providing a die attach layer between the semiconductor die and the copper layer, the die attach layer comprising a polymer matrix and a nano-metal particle filler.

### BRIEF DESCRIPTION OF THE DRAWINGS

The accompanying drawings illustrate exemplary approaches of the disclosed embodiments so far devised for the practical application of the principles thereof, and in which:

FIG. 1 is a perspective view of a semiconductor package assembly according to exemplary embodiments of the disclosure;

FIG. 2 is a cross sectional view of the semiconductor package assembly of FIG. 1, along cut line 2-2, according to exemplary embodiments of the disclosure; and

FIG. 3 demonstrates a process for forming a semiconductor package assembly according to embodiments of the present disclosure.

The drawings are not necessarily to scale. The drawings are merely representations, not intended to portray specific parameters of the disclosure. Furthermore, the drawings are intended to depict exemplary embodiments of the disclosure, and therefore is not considered as limiting in scope.

Furthermore, certain elements in some of the figures may be omitted, or illustrated not- to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

The present disclosure will now proceed with reference to the accompanying drawings, in which various approaches are shown. It will be appreciated, however, that the power electronic packages may be embodied in many different forms and should not be construed as limited to the approaches set forth herein. Rather, these approaches are provided so that this disclosure will be thorough and complete, and will fully convey the scope of the disclosure to those skilled in the art. In the drawings, like numbers refer to like elements throughout.

Embodiments herein provide a novel power device packaging design effective for lowering the thermal resistance to provide more efficient power and thermal performance. The power device packaging provides hotspot thermal management by keeping a junction temperature of the power device lower during application. More specifically, to keep the junction temperature of the device at an optimum level, a thermally conductive nano-metal (e.g., Ag) die attach material may be provided as part of the power device. The nano-Ag die attach material may advantageously replace currently used die attach materials, such as solder, in power electronics.

As will be described in greater detail herein, the nano-metal material is used in the selection of package material to develop the optimum package model in the power electronics application. For example, a sintered nano-Ag die attach material has a higher thermal conductivity and electrical conductivity (e.g., 200 W/m-K and 3.8×105 (Ω-cm)−1), which enables a high power and high temperature application with robust and stable functioning capabilities without significant deterioration in terms of switching speeds, junction temperatures, power density, etc.

As will be evident from the disclosure, embodiments herein provide at least the following additional technical advantages. Firstly, a sintered nano-Ag die attach material has better thermal performance then other die attach materials, such as Ag-epoxy, solder, etc. Secondly, the package design provides a compact, smaller size Restriction of Hazardous Substances (ROHS) compliant application. Thirdly, productivity may be increased, and expenses reduced due to a more optimal combination of die and die attach material.

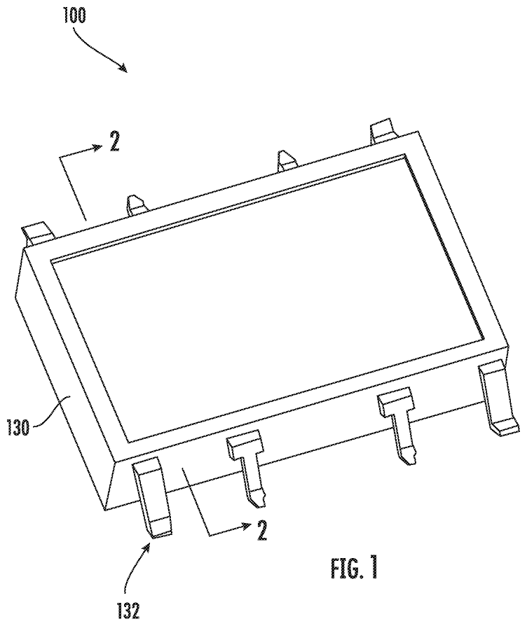

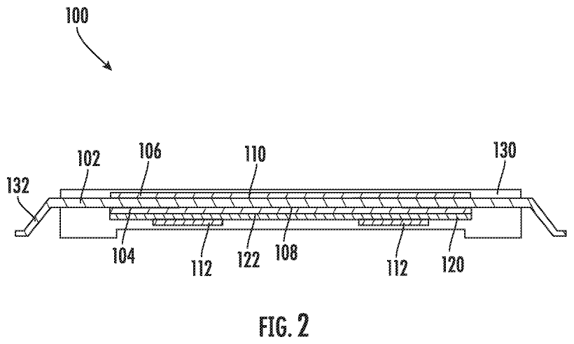

Turning now to FIGS. 1-2, a semiconductor package assembly (hereinafter “assembly”) 100 according to embodiments of the present disclosure will be described. As shown, the assembly 100 may include a substrate 102 sandwiched by a first metallization layer 104 and a second metallization layer 106. In the orientation depicted, the first metallization layer 104 may be disposed adjacent a bottom side 108 of the substrate 102, while the second metallization layer 106 may be disposed adjacent a top side 110 of the substrate 102. In some embodiments the substrate 102 includes aluminum oxide. In some embodiments, the first metallization layer 104 and the second metallization layer 106 are copper.

The assembly 100 may further include one or more semiconductor dies 112 disposed in thermal contact with the first metallization layer 104. In some embodiments, the semiconductor dies 112 may be power MOSFET or IGBT devices. Although non-limiting, the semiconductor dies 112 may include silicon carbide.

The assembly may further include a die attach layer 120 disposed between the semiconductor dies 112 and the first metallization layer 104. Said differently, the die attach layer 120 may be in direct contact with a bottom surface 122 of the first metallization layer 104. The die attach layer 120 may include a polymer matrix, such as an epoxy matrix, and a nano-metal particle filler, such as Ag. In some embodiments, the nano-metal is nano-Ag. Although non-limiting, the die attach layer 120 may have a thermal conductivity of at least 150 W/m-k.

Furthermore, the die attach layer 120 may include a nano-Ag sintered epoxy material having a cure temperature of 200° C. or less. Embodiments herein are not limited in this context.

The assembly 100 may further include a surface mount device including an encapsulation 130 and a set of leads 132 coupled to the substrate 102 and the first metallization layer 104. In some embodiments, the leads 132 may be copper or any other suitable conductor.

The thermal distribution or hotspot thermal management of the assembly 100, including SiC semiconductor dies 112 with nano-Ag die attach layer 120, is an improvement over the thermal distribution of semiconductor dies attached with solder. Application of nano-Ag die attach layer 120 in power packages keeps the hotspot cool by delivering more heat to the outside of the package environment.

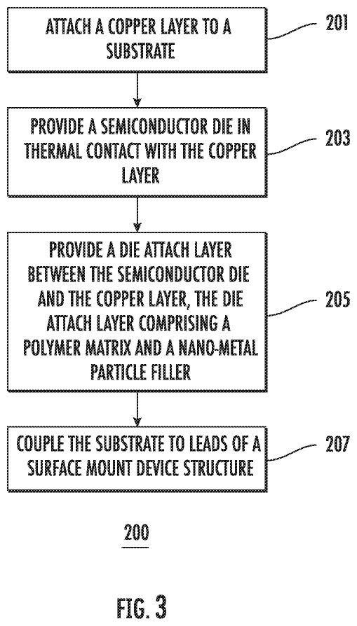

Turning now to FIG. 3, a method 200 of forming a semiconductor package assembly having increased thermal performance will be described. As shown, at block 201, the method 200 may include attaching a copper layer to a substrate. In some embodiments, the substrate is made from aluminum oxide.

At block 203, the method 200 may include providing a semiconductor die in thermal contact with the copper layer. In some embodiments, multiple semiconductor dies may be coupled to the copper layer. In some embodiments, the semiconductor die is made from silicon carbide.

At block 205, the method 200 may further include providing a die attach layer between the semiconductor die and the copper layer, the die attach layer comprising a polymer matrix and a nano-metal particle filler. In some embodiments, the die attach layer may include a polymer matrix, such as an epoxy, and a nano-metal particle filler, such as Ag. In some embodiments, the nano-metal is nano-Ag. Although non-limiting, the die attach layer may have a thermal conductivity of at least 150 W/m-k. Furthermore, the die attach layer may include a nano-Ag sintered epoxy material having a cure temperature of 200° C. or less.

At block 207, the method 200 may further include coupling the substrate to leads of a surface mount device structure.

The foregoing discussion has been presented for purposes of illustration and description and is not intended to limit the disclosure to the form or forms disclosed herein. For example, various features of the disclosure may be grouped together in one or more aspects, embodiments, or configurations for the purpose of streamlining the disclosure. However, it should be understood that various features of the certain aspects, embodiments, or configurations of the disclosure may be combined in alternate aspects, embodiments, or configurations. Moreover, the following claims are hereby incorporated into this Detailed Description by this reference, with each claim standing on its own as a separate embodiment of the present disclosure.

As used herein, an element or step recited in the singular and proceeded with the word “a” or “an” should be understood as not excluding plural elements or steps, unless such exclusion is explicitly recited. Furthermore, references to “one embodiment” of the present disclosure are not intended to be interpreted as excluding the existence of additional embodiments that also incorporate the recited features.

The use of “including,” “comprising,” or “having” and variations thereof herein is meant to encompass the items listed thereafter and equivalents thereof as well as additional items. Accordingly, the terms “including,” “comprising,” or “having” and variations thereof are open-ended expressions and can be used interchangeably herein.

The phrases “at least one”, “one or more”, and “and/or”, as used herein, are open-ended expressions that are both conjunctive and disjunctive in operation. For example, each of the expressions “at least one of A, B and C”, “at least one of A, B, or C”, “one or more of A, B, and C”, “one or more of A, B, or C” and “A, B, and/or C” means A alone, B alone, C alone, A and B together, A and C together, B and C together, or A, B and C together.

All directional references (e.g., proximal, distal, upper, lower, upward, downward, left, right, lateral, longitudinal, front, back, top, bottom, above, below, vertical, horizontal, radial, axial, clockwise, and counterclockwise) are only used for identification purposes to aid the reader's understanding of the present disclosure, and do not create limitations, particularly as to the position, orientation, or use of this disclosure. Connection references (e.g., attached, coupled, connected, and joined) are to be construed broadly and may include intermediate members between a collection of elements and relative movement between elements unless otherwise indicated. As such, connection references do not necessarily infer that two elements are directly connected and in fixed relation to each other.

Furthermore, identification references (e.g., primary, secondary, first, second, third, fourth, etc.) are not intended to connote importance or priority, but are used to distinguish one feature from another. The drawings are for purposes of illustration only and the dimensions, positions, order and relative sizes reflected in the drawings attached hereto may vary.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, although the illustrative method 200 is described above as a series of acts or events, the present disclosure is not limited by the illustrated ordering of such acts or events unless specifically stated. For example, some acts may occur in different orders and/or concurrently with other acts or events apart from those illustrated and/or described herein, in accordance with the disclosure. In addition, not all illustrated acts or events may be required to implement a methodology in accordance with the present disclosure. Furthermore, the method 200 may be implemented in association with the formation and/or processing of structures illustrated and described herein as well as in association with other structures not illustrated.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

1. A semiconductor package assembly, comprising:
a substrate;
a first metallization layer disposed adjacent the substrate;
a semiconductor die disposed in thermal contact with the first metallization layer; and
a die attach layer disposed between the semiconductor die and the first metallization layer, the die attach layer comprising a polymer matrix and a nano-metal particle filler.

2. The semiconductor package assembly of claim 1, the substrate comprising aluminum oxide.

3. The semiconductor package assembly of claim 1, the semiconductor die comprising silicon carbide.

4. The semiconductor package assembly of claim 1, further comprising a second semiconductor die disposed in thermal contact with the first metallization layer.

5. The semiconductor package assembly of claim 1, the semiconductor die comprising a power MOSFET or an IGBT device.

6. The semiconductor package assembly of claim 1, the nano-metal particle filler comprising a silver nano-metal material.

7. The semiconductor package assembly of claim 1, wherein the die attach layer has a thermal conductivity of at least 150 W/m-K.

8. The semiconductor package assembly of claim 1, the die attach layer comprising an epoxy matrix and silver nano-particle filler.

9. The semiconductor package assembly of claim 1, the die attach layer comprising an epoxy material having a cure temperature of 200° C. or less.

10. The semiconductor package assembly of claim 1, further comprising a surface mount device structure including a set of leads coupled to the substrate.

11. The semiconductor package assembly of claim 1, further comprising a second metallization layer.

12. The semiconductor package assembly of claim 11, wherein the first metallization layer and the second metallization layer are copper.

13. A semiconductor package assembly, comprising:
a substrate;
a copper layer disposed adjacent to the substrate;
a semiconductor die disposed in thermal contact with the copper layer; and
a die attach layer disposed between the semiconductor die and the copper layer, the die attach layer comprising a polymer matrix and a nano-metal particle filler.

14. The semiconductor package assembly of claim 13, the substrate comprising aluminum oxide, and the semiconductor die comprising silicon carbide.

15. The semiconductor package assembly of claim 13, further comprising a second semiconductor die disposed in thermal contact with the copper layer.

16. The semiconductor package assembly of claim 13, the nano-metal particle filler comprising a silver nano-metal material.

17. The semiconductor package assembly of claim 13, the die attach layer comprising an epoxy matrix and silver nano-particle filler.

18. A method of forming a semiconductor package assembly, the method comprising:
coupling a copper layer to a substrate;
providing a semiconductor die in thermal contact with the copper layer; and
providing a die attach layer between the semiconductor die and the copper layer, the die attach layer comprising a polymer matrix and a nano-metal particle filler.

19. The method of claim 18, further comprising coupling the substrate to leads of a surface mount device structure.

20. The method of claim 18, further comprising coupling a second copper layer to the substrate.
